(19) United States
(12) Patent Application Publication
(10) Pub. No.: US 2026/0133236 A1
(43) Pub. Date: May 14, 2026

(54) CAPACITOR BANK CONTROL SYSTEM

(71) Applicant: Eaton Intelligent Power Limited, Dublin (IE)

(72) Inventors: Rajan Tribhuvan, Nashik (IN); Girish Mane, Pune (IN); Troy D. Hedlund, Rogers, MN (US); Manishkumar Sharma, Pune (IN); Kevin Allmaras, Carrington, ND (US); Siddhesh Mehta, Dapoli (IN); Jay Padgilwar, Nagpur (IN); Vikrant Mohanty, Pune (IN); Michael Douglas Manning, Finksburg, MD (US); Alexander William Tibbetts, Chanhassen, MN (US)

(21) Appl. No.: 19/384,774

(22) Filed: Nov. 10, 2025

(30) Foreign Application Priority Data
Nov. 14, 2024 (IN) 202411087967

(51) Int. Cl. G01R 31/08; H02B 1/30; H02B 1/52; H02J 3/14; H02J 3/16

(52) U.S. Cl. CPC G01R 31/088; H02B 1/303; H02B 1/52; H02J 3/16; H02J 3/17

(57) ABSTRACT

A control system includes: a sensor system configured to produce an indication of one or more measured electrical properties of a multi-phase electrical distribution system; a relay system configured control an electrical connection between the electrical distribution system and a capacitor bank; a communications device; and a controller coupled to the communications device. The controller is configured to: access the indication of the one or more measured electrical properties of the multi-phase electrical distribution system; analyze the indication of the one or more measured electrical properties of the multi-phase electrical distribution system to determine whether a fault condition exists in the multi-phase electrical distribution system; and if a fault condition exists, provide a notification of the fault condition to a remote device through the communications device.

### CROSS-REFERENCE TO RELATED APPLICATION

This application claims priority to Indian Patent Application number 202411087967, filed Nov. 14, 2024 and titled CAPACITOR BANK CONTROL SYSTEM, which is incorporated herein by reference in its entirety.

### TECHNICAL FIELD

This disclosure relates to a capacitor bank control system.

### BACKGROUND

An electrical power grid includes one or more sources of electricity, one or more loads, and mechanisms for distributing electrical power from the sources to the loads. Inductive loads cause poor power factor which leads to increased line losses, decreased capacity, and wasted generation. Capacitor banks are used to maintain power factor on the electrical power grid.

### SUMMARY

In one aspect, a control system includes: a sensor system configured to produce an indication of one or more measured electrical properties of a multi-phase electrical distribution system; a relay system configured control an electrical connection between the electrical distribution system and a capacitor bank; a communications device; and a controller coupled to the communications device. The controller is configured to: access the indication of the one or more measured electrical properties of the multi-phase electrical distribution system; analyze the indication of the one or more measured electrical properties of the multi-phase electrical distribution system to determine whether a fault condition exists in the multi-phase electrical distribution system; and if a fault condition exists, provide a notification of the fault condition to a remote device through the communications device.

Implementations may include one or more of the following features.

The controller may be configured to determine whether the indication of the one or more measured electrical properties includes a spike in amplitude of electrical current followed by a loss of power over a predetermined time period in one or more phases of the electrical distribution system to determine whether the fault condition exists.

The predetermined time period may be a user-entered value. The controller may be further configured to provide a report regarding the fault condition to the remote device in response to a request for the report. The report may include one or more of a type of fault condition, a direction of the fault condition, a location of the fault condition, and oscillography related to the fault condition. The controller may include an electronic storage, the electronic storage including a library of waveforms, each waveform associated with one or more known types of fault conditions. The controller also may be configured to compare a representation of a waveform based on the indication of the one or more measured electrical properties of the multi-phase electrical distribution system to waveforms in the library of waveforms to identify the type of fault condition.

In another aspect, a control system includes: a sensor system configured to produce an indication of one or more measured electrical properties of each phase of a multi-phase electrical distribution system; a relay system configured control a plurality of electrical connections, each electrical connection being between one phase of the electrical distribution system and a corresponding phase of a capacitor bank; and a controller configured to: access the indication of the one or more measured electrical properties of the multi-phase electrical distribution system; analyze the indication of the one or more measured electrical properties of the multi-phase electrical distribution system to determine whether an unbalanced condition exists in one or more of the phases of the electrical distribution system; and if an unbalanced condition exists, cause the relay system to control at least one electrical connection between at least one phase of the electrical distribution.

Implementations may include one or more of the following features.

The controller may be configured to analyze the indication of the one more measured electrical properties to determine if an imbalance exists in the multi-phase electrical distribution system, and, if an imbalance exists, cause the relay system to control the electrical connection between any of the phases of the capacitor bank individually or all of the phases of the capacitor bank simultaneously based on the analysis.

In some implementations, before causing the relay system to control the at least one electrical connection, the controller is further configured to determine whether controlling the at least one electrical connection would correct the unbalanced condition.

In another aspect, an enclosure for a controller includes: a housing including: a base portion with an interior region, and a cover configured to be attached to and removed from the base portion, and, when the cover is attached to the base portion, the interior region is enclosed; a metallic housing in the interior region; a connector that extends through the metallic housing and is coupled to the control system, the connector configured to receive an indication of one or more measured electrical properties in an electrical distribution system and to provide a control signal to a relay; a control system in the metallic housing and coupled to the connector, the control system configured to generate the control signal based on the indication of the one or more measured electrical properties; a communications device configured to communicate with the control system; and a power source in the interior region and electrically connected to the control system and the communications device.

Implementations may include one or more of the following features.

The cover may include a door attached to one side of the base.

The communications device may include a modem, and the enclosure further includes a breaker configured as a power switch in the interior region.

In another aspect, an enclosure for a capacitor bank controller includes: a base including: a plurality of sidewalls and a back portion, a first side of each of the plurality of sidewalls and the back portion defining an interior region, with a second side of a first one of the sidewalls including a latch connection region; a cover rotatably mounted to a second one of the sidewalls and configured to rotate about the second one of the sidewalls; and a latch mounted to a first side of the cover. When the cover is positioned with the cover over the interior region, the latch is aligned with the latch recess, a second side of the cover faces the interior region, and the latch includes a single-piece handle configured to be secured to the latch connection region with a single movement.

Implementations may include one or more of the following features.

The second side of the first one of the sidewalls also may include a handle. The handle may include a recess in the second side of the first one of the sidewalls.

The second one of the sidewalls may be parallel to the first one of the sidewalls.

Each of the second side of the first one of the sidewalls and the second side of the second one of the sidewalls may include a respective first and second handle. The first handle may include a recess in the second side of the first one of the sidewalls, and the second handle may include a recess in the second side of the second one of the sidewalls.

The enclosure also may include a hanging bracket configured to attach to a second side of the back portion, and the hanging bracket may include an interface configured to attach the enclosure to a utility structure.

In another aspect, a control system includes: a sensor system configured to produce an indication of one or more measured electrical properties of each phase of a multi-phase electrical distribution system; a relay system configured control a plurality of electrical connections, each electrical connection being between one phase of the electrical distribution system and a corresponding phase of a capacitor bank; and a controller configured to perform an automated commissioning of the capacitor bank. The automated commissioning includes the controller being configured to: present information related to settings; perform wiring verification to confirm that the capacitor bank operates; if the capacitor bank operates, cause the relay system to control a switch on the electrical connection between one phase of the distribution system and the corresponding phase of the capacitor bank; and confirm that the switch operated.

Implementations of any of the techniques described herein may include a system, a control board, a control system, an enclosure, or a method. The details of one or more implementations are set forth in the accompanying drawings and the description below. Other features will be apparent from the description and drawings, and from the claims.

### DRAWING DESCRIPTION

FIG. 1 is a block diagram of a system.

FIGS. 2A-2C show an outer enclosure for a capacitor bank control system.

FIG. 3 is an exploded view of another outer enclosure for a capacitor bank control system.

FIGS. 4A-4F relate to another outer enclosure for a capacitor bank control system.

FIG. 5 shows another outer enclosure for a capacitor bank controls system.

FIG. 6 is a block diagram of a capacitor control board.

FIG. 7 is a flow chart of a process for detecting a fault condition in a power distribution system.

FIG. 8 is a flow chart of a process for preventing an unbalance condition in a power distribution system.

FIG. 9 is a flow chart of a process for evaluating and detecting an unbalance system and correcting it by requesting a single-phase operation of the capacitor bank.

### DETAILED DESCRIPTION

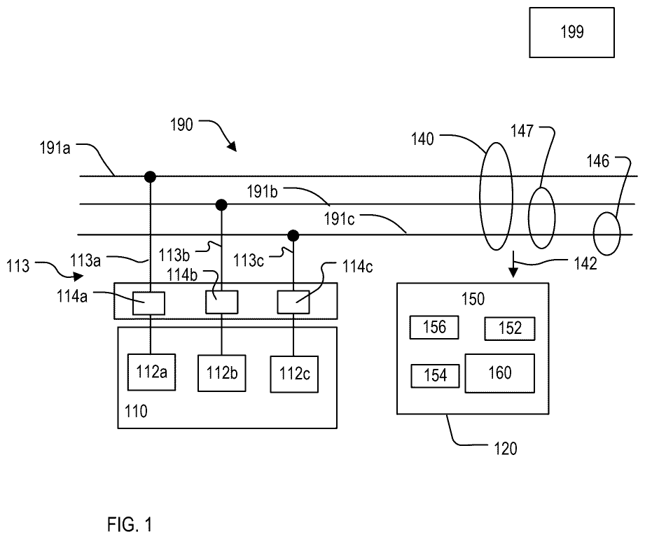

FIG. 1 is a block diagram of a system 100. The system 100 includes an electrical power distribution system 190, a capacitor bank 110, and a capacitor bank control system 150 that opens and closes a three-phase electrical connection 113 between the distribution system 190 and the capacitor bank 110. The control system 150 also monitors electrical conditions in the distribution system 190 and operates the capacitor bank to correct of out-of-band voltages and power factor. Moreover, and as discussed below, the control system 150 detects fault conditions in the distribution system 190 and reports outages in the distribution system 190, and detects and corrects voltage imbalance conditions in the distribution system 190. Furthermore, the control system 150 may be packaged in an outer enclosure 120 that allows the capacitor bank control system 150 to be handled more easily than a typical housing for a control system, thereby making the capacitor bank control system 150 easier to install and easier to transport. Before discussing various implementations and features of control system 150 in more detail, an overview of the system 100 is provided.

The electrical distribution system 190 is a multi-phase distribution system that includes phase conductors 191a, 191b, 191c. The distribution system 190 also may include a neutral line that is not shown. In other words, the distribution system 190 may be a three-phase, four-wire distribution system. The electrical power distribution system 190 may be, for example, an electrical grid, an electrical system, or a multi-phase electrical network that provides electricity to commercial, industrial, municipal, and/or residential customers. The electrical power distribution system 190 may have an operating voltage of, for example, at least 1 kV, up to 34.5 kV, or up to 38 kV. The electrical power distribution system 190 is an alternating current (AC) electrical network and may operate at a fundamental frequency of, for example, 50 or 60 Hertz (Hz). The distribution system 190 includes devices that transfer, consume, and/or generate electrical power. For example, the distribution system 190 may include distribution lines and electrical cables, transformers, voltage regulators, reclosers, surge protectors, generators, substations, distributed energy resources, and power converters.

The distribution system 190 also includes various structures, such as, for example, utility poles and cabinets. The phase conductors 191a, 191b, 191c may be overhead distribution lines that are mounted on an above-ground support such as a utility pole, frame, or piling. In these implementations, the capacitor bank 110 and the capacitor bank control system 150 also may be mounted to the above-ground support. In some implementations, some portions of the phase conductors 191a, 191b, 191c are underground. In these implementations, the capacitor bank 110 may be in a pad-mounted cabinet or a vault and the capacitor bank control system 150 may be mounted on the cabinet or vault. The capacitor bank control system 150 may be used in a substation.

The capacitor bank 110 is a three-phase capacitor bank that includes capacitive networks 112a, 112b, 112c, one for each phase. Each capacitive network 112a, 112b, 112c includes one or more capacitive devices and all of the capacitive networks 112a, 112b, 112c have the same nominal capacitance. The capacitive device(s) in each network 112a, 112b, 112c may be arranged in any manner. For example, each capacitive network 112a, 112b, 112c may include one capacitor or a collection of capacitors connected to each other in series and/or parallel.

Each capacitive network 112a, 112b, 112c is electrically connected to a respective controllable switch apparatus 114a, 114b, 114c. The control system 150 controls the state of the switch apparatuses 114a, 114b, 114c to thereby control a respective electrical connection 113a, 113b, 113c between one phase of the electrical power distribution system 190 and a corresponding phase of the capacitor bank 110. For example, when the switch apparatus 114a is closed, the capacitive network 112a is electrically connected to the phase conductor 191a. When the switch apparatus 114a is opened, the capacitive network 112a is not electrically connected to the phase conductor 191a. The capacitor bank control system 150 may control the switch apparatuses 114a, 114b, 114c in a ganged manner such that all of the switch apparatuses 114a, 114b, 114c open or close simultaneously or in a per-phase manner.

The capacitor bank control system 150 includes a power transformer wired in either a wye 146 or delta 147 configuration to power the unit and exercise the switches, sensor system 152, an electronic control 160, a communications device 154, and a relay system 156. The sensor system 152 receives measured data 142 from a sensor 140 and produces an indication of the measured data. The sensor 140 may be a voltage sensor, a current sensor, or a power sensor. The sensor 140 measures one or more properties of the electricity each phase conductor 191a, 191b, 191c. For example, the sensor 140 may include three voltage sensors and/or three current sensors, one for each phase conductor 191a, 191b, 191c. Power transformers 146 and/or 147 can be used to measure data as well.

The electronic control 160 processes the indication of the measured data and also commands the relay system 156. The electronic control 160 is any type of electronic control device. For example, the electronic control 160 may be a microcontroller. The relay system 156 may include six relays, two for each phase of the capacitor bank 110. In these implementations, the relay system 156 includes a trip relay and a close relay for each phase of the capacitor bank 110. The relay system 156 operates to route secondary power to the switches 114a, 114b, 114c in a ganged or per-phase fashion to exercise the switches and put the capacitive networks in the state that the electronic control 160 has determined most beneficial to the distribution system 190. The electronic control 160 controls the relay system 156 to open and close the electrical connections 113a, 113b, 113c in a ganged or per-phase manner.

The communications device 154 is any type of device capable of communicating with a remote device or remote station 199 that is separate from the capacitor bank control system 150. The communications device 154 may be, for example, an antenna, modem, and/or a physical interface or socket (such as a Universal Serial Bus (USB) interface or an Ethernet interface). The communications device 154 may be capable of communicating via any wireless or wired protocol. Examples of protocols include, without limitation, Ethernet, Transmission Control Protocol/Internet Protocol (TCP/IP), a protocol based on the IEEE 802.11 standard (such as Wi-Fi), Global System for Mobile Communications (GSM), Global Positioning System (GPS), and Supervisory Control and Data Acquisition (SCADA). The capacitor bank control system 150 may include more than one communications device 154 and more than one type of communications device 154. For example, the capacitor bank control system 150 may include communications devices for wired communication and communications devices for wireless communication.

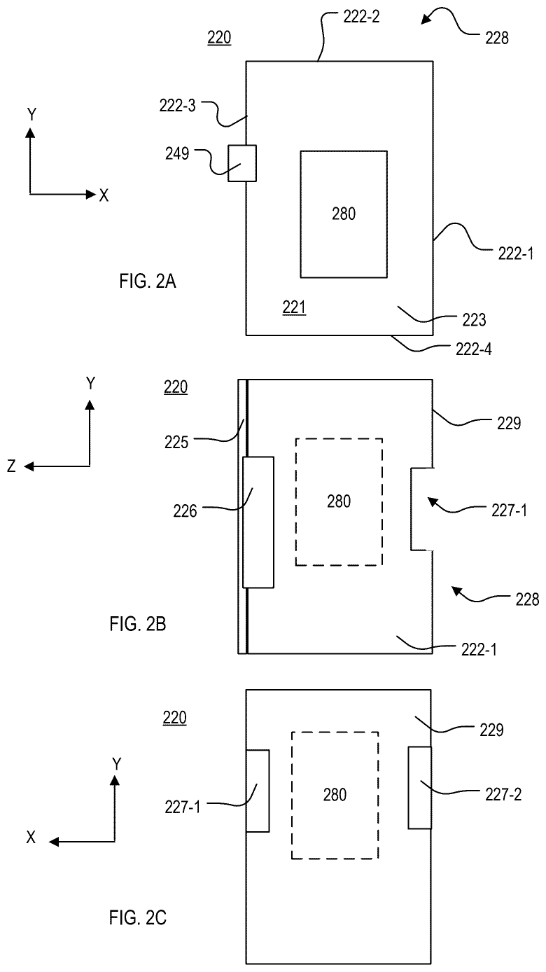

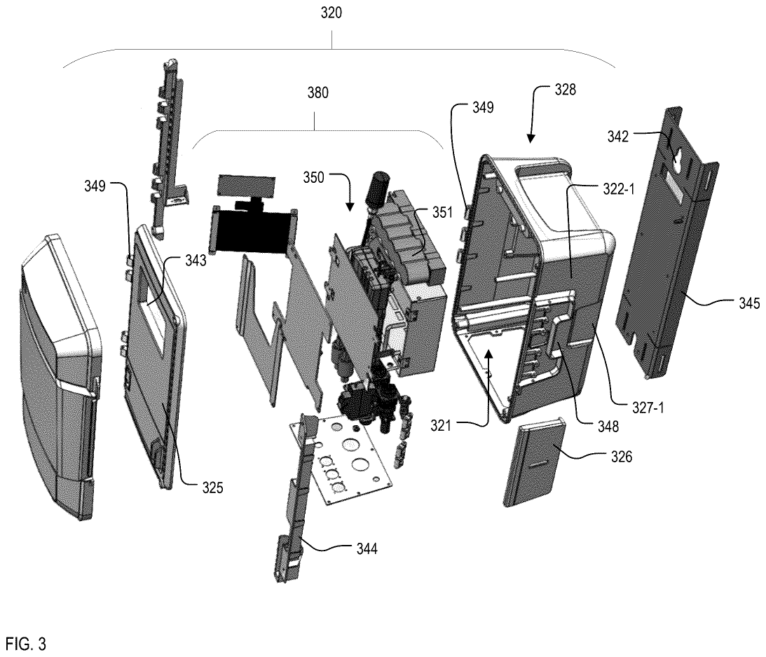

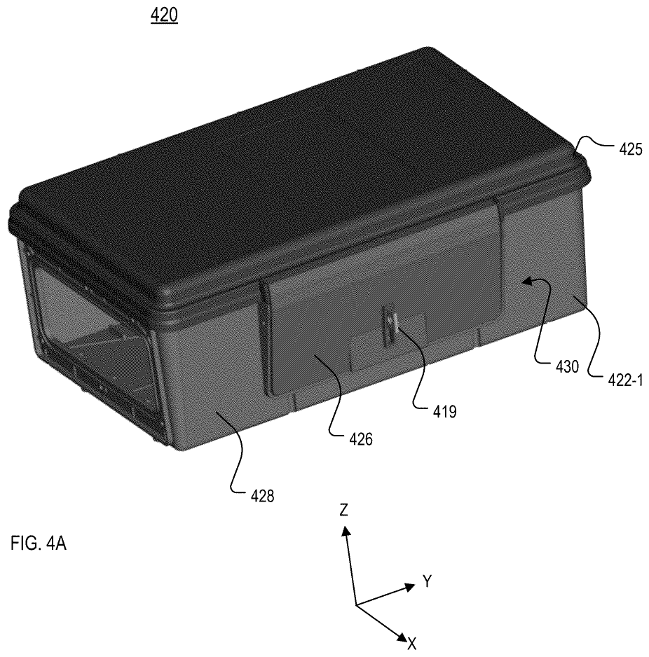

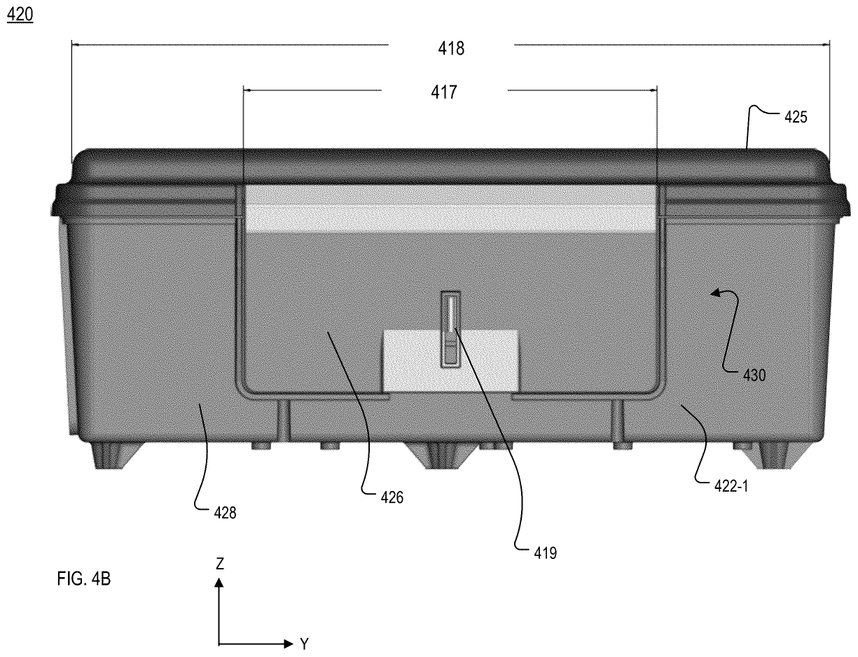

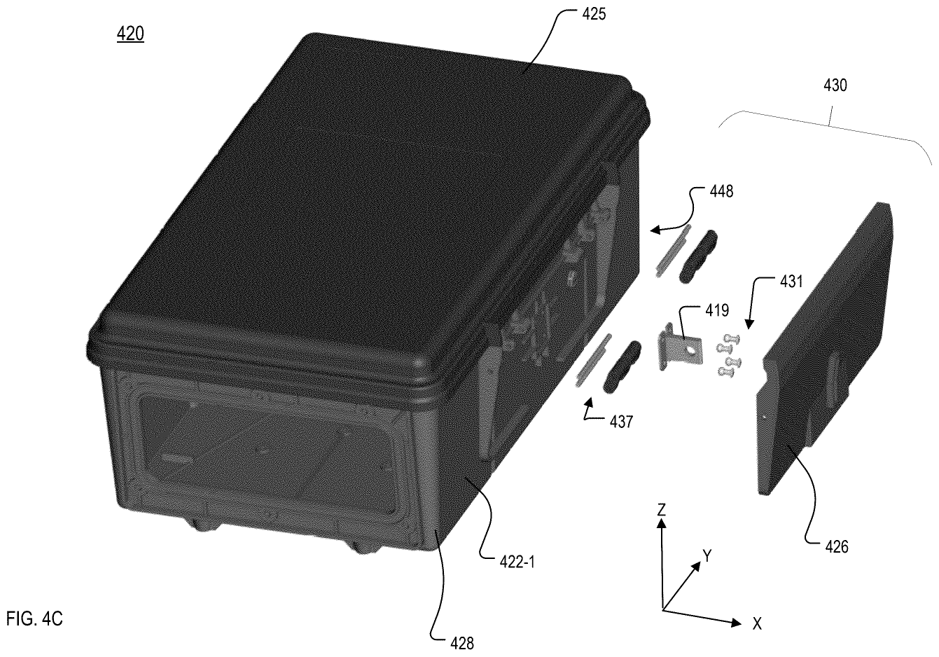

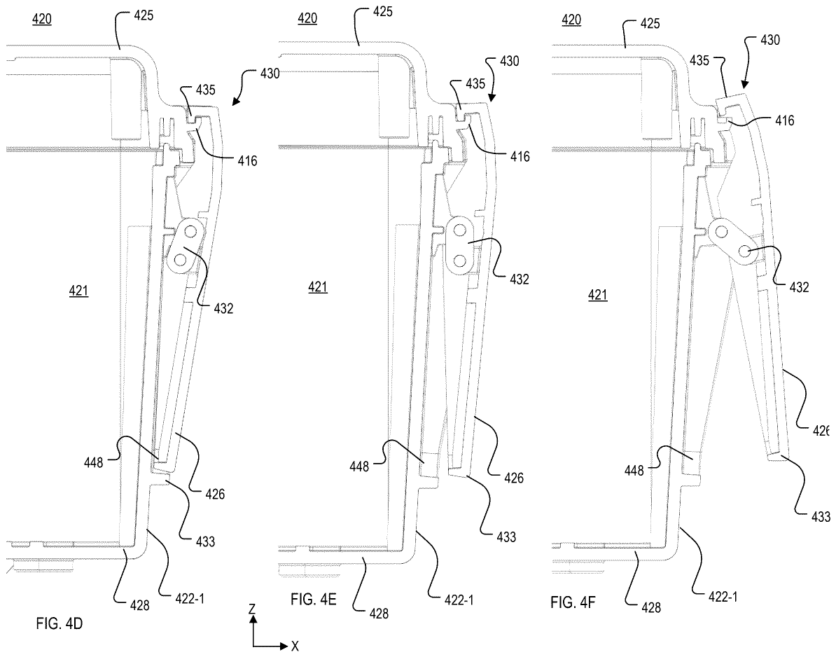

FIGS. 2A-2C show an outer enclosure 220 for a capacitor bank control system. FIG. 2A shows a base 228 of the outer enclosure 220 with an interior region 221 exposed. The outer enclosure 220 is made of a sturdy material such as a rugged polymer; a material that includes fiberglass, such as fiberglass reinforced polycarbonate; or a polycarbonate resin thermoplastic. The base 228 includes a back wall 223 and sidewalls 222-1, 222-2, 222-3, 222-4 that extend in the Z direction (out of the page of FIG. 2A) from the back wall 223. The sidewalls 222-1 and 222-3 are parallel to each other, and the sidewalls 222-2 and 222-4 are parallel to each other. The sidewalls 222-1, 222-2, 222-3, 222-4 form a rectangular perimeter that is substantially perpendicular to the back wall 223 and surround the interior region 221. An inner enclosure 280 is in the interior region 221. The inner enclosure 280 is a metallic enclosure that houses a control system (such as the control system 150 of FIG. 1). Additional examples of the inner enclosure 280 are discussed with respect to FIGS. 3 and 4.

FIG. 2B is a side exterior view of the outer enclosure 220 with a cover 225 positioned over the interior region 221. The cover 225 is a door that is attached to the base 228 at a hinged connection 249 on the sidewall 222-3. The cover 225 rotates about the hinged connection 249 to expose or enclose the interior region 221. FIG. 2B shows the cover 225 positioned to enclose the interior region 221. In FIG. 2B, the inner enclosure 280 depicted with a dashed line to indicate that it is a hidden element.

The cover 225 includes a latch 226 that engages with a corresponding connection point on the exterior side of the sidewall 222-1. The latch 226 is a single clam shell clamp with a single locking clasp. FIGS. 4A-4E provide additional discussion of an implementation of the latch 226. When the latch 226 is engaged to the sidewall 221-2, the cover 225 is temporarily secured and the inner enclosure 280 is enclosed in the interior region 221. The latch 226 is configured to be operated in a single motion and/or with a single hand. For example, the latch 226 may be an ergonomic latch that is easily graspable by a human hand. The latch 226 may be latched and unlatched with one motion and with one hand and without the use of additional tools. This improves the usability of the outer enclosure 220. For example, the outer enclosure 220 may be attached at or near the top of a utility pole or on another structure reachable by an operator only by standing on a device such as a ladder, bucket truck, or lift. Such devices may be unstable. Moreover, repairs may occur during inclement weather or under dangerous conditions. On the other hand, the latch 226 allows an operator to open the outer enclosure 220 quickly and easily, thereby reducing risk to the operator and facilitating efficient maintenance.

Referring also to FIG. 2C, which is a back exterior view of the outer enclosure 220. The outer enclosure 220 includes the back wall 223, which has an exterior side 229. Two recesses 227-1 and 227-2 extend into the exterior side 229. The recesses 227-1 and 227-2 are sized to allow a human operator to lift and carry the outer enclosure 220. The presence of the recesses 227-1 and 227-2 facilitates efficient transfer of the outer enclosure 220. For example, the recesses 227-1 and 227-2 allow the outer enclosure 220 to be moved about a manufacturing or storage facility easily or carried to a truck or other vehicle for transport to an installation site. Moreover, the recesses 227-1 and 227-2 provide a mechanism for an operator to hold the outer enclosure 220 while, for example, riding in a bucket of a bucket truck.

The outer enclosure 220 shown in FIGS. 2A-2C is provided as an example, and other implementations are possible. For example, the outer enclosure 220 may be implemented to include the latch 226 but without the recesses 227-1 and 227-2. In another example, the outer enclosure 220 may be implemented with one recess instead of two, and the recess(s) may be positioned on other parts of the back wall. The recesses 227-1 and 227-1, the base 228, and/or the cover 225 may have shapes and configurations other than shown in FIGS. 2A-2C.

FIG. 3 is an exploded perspective view of another example of an outer enclosure 320 for a capacitor bank control system. The outer enclosure 320 includes a base 328 that defines an interior region 321 and a door 325 that, when secured to the base 328, encloses the interior region 321. The base 328 includes a sidewall 322-1 with a latch connection point 348 and a recess 327-1. The door 325 is rotateably attached to the base 328 with a hinge element 349. The door 325 includes a window 343 that allows some of the interior region 321 to be seen when the door 325 is closed. For example, the window 343 may be aligned with an LCD display of a control system 350 that is housed in an inner enclosure 380. The inner enclosure 380 includes a control board and a power supply 351. The power supply 351 may be, for example, a super capacitor.

The outer enclosure 320 also includes a latch 326. When assembled, the latch 326 is attached to the door 325 at a hinge mount 344. The latch 326 includes surface features that match with surface features of in the latch connection point 348. For example, the latch 326 may include protrusions, tabs, and recesses that interact with corresponding surface features in the latch connection point 348 to removably secure the latch 326 to the latch connection point 348. For example, the surface features on the latch 326 may interact with the corresponding surface features in the latch connection point 348 by a frictional engagement or snap fit. The latch 326 is configured to be operated with one hand and may be opened or closed in a single motion. Moreover, the latch 326 is designed to be opened and closed without the use of tools. The base 328 also includes a recess 327-1 and may include an identical recess 327-1 on the opposite side of the base 328. The recess 327-1 is sized to act as a handle for transporting the outer enclosure 320.

The outer enclosure 320 may be mounted onto a support structure (such as pole, rack, or cross arm) with a mounting bracket 345. The mounting bracket 345 is attached to the base 328 at an exterior back wall 329. The mounting bracket 345 includes a keyhole 342 that is placed over a hook or other holding point on the support structure to thereby mount the assembled outer enclosure 320 to the support structure.

FIG. 4A is a perspective exterior view of another example of an outer enclosure 420. The outer enclosure 420 includes a base 428 and a door 425 that is removably secured to the base 428 with a latch system 430. When the door 425 is opened, an interior region 421 (FIGS. 4D-4F) is accessible. When the door 425 is closed (as shown in FIG. 4A), the interior region 421 is enclosed.

The latch system 430 includes a single-piece latch handle 426. Some legacy enclosures for capacitor bank control systems include a door with two latch handles, both of which must be opened to release the door and both of which must be closed to secure the door in the closed position. The placement and configuration of the two latch handles may prohibit opening or closing the door with a single hand and/or in a single motion. On the other hand, the door 425 of the outer enclosure 420 uses the latch handle 426, which is a single-piece latch that may be operated with one hand and/or in a single motion. In this way, the door 425 is easier to open and close as compared to a legacy design that uses a two-piece latch or a multi-piece latch. Additionally, the latch system 430 includes a padlock, hasp, or staple feature 419 that eliminates the two locks that are typically used in a legacy two-piece latch. Thus, the latch system 430 reduces costs and part count.

FIG. 4B is a side exterior view of the outer enclosure 420. The outer enclosure 420 has an extent 418 in the Y direction and the latch handle 426 has an extent 417 in the Y direction. The latch handle 426 is relatively wide. For example, the extent 417 may be about 60% of the extent 418.

FIG. 4C is a perspective view of the outer enclosure 420 with the latch system 430 shown in an exploded view. The latch system 430 includes the latch handle 426, the securing feature 419, and connection mechanisms 437. A latch connection point 448 is formed into a sidewall 422-1 of the base 428.

FIGS. 4D-4F are side cross-sectional views of the latch system 430. FIG. 4D shows the latch system 430 in the closed position. FIG. 4E shows the latch system 430 in a balance point. FIG. 4F shows the latch system 430 in the open position. Referring to FIG. 4D, when the latch system 430 is in the closed position, the latch handle 426 is in contact with the latch connection point 448. A top portion 435 of the latch handle 426 is engaged with a corresponding surface feature 416 on the door 425. Referring to FIG. 4E, pulling on a bottom area 433 of the latch handle 426 moves a latch joint 432 to the vertical position (the Z axis in this example). The top portion 435 depresses the door 425 slightly. In the balance point, the latch handle 426 can snap closed or open. Continuing to pull the latch handle 426 away from the sidewall 422-1 opens the latch system 430. Referring to FIG. 4E, the latch handle 426 is loose and can be unhooked from the surface feature 416 on the door 425, thereby allowing the door 425 to open. The latch system 430 is closed by following this procedure in reverse.

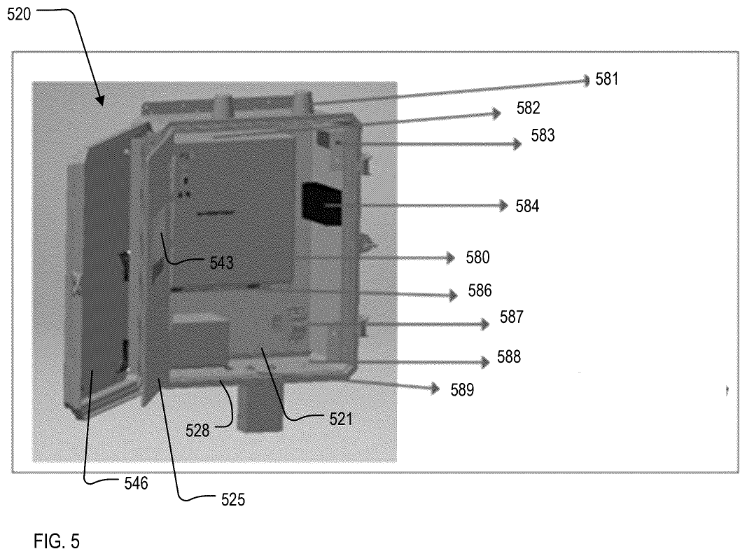

FIG. 5 is a perspective front view of another outer enclosure 520. The outer enclosure 520 includes a door 525 and a base 528. The base defines an interior region 521, which is exposed when the door 525 is opened (as shown in FIG. 5). The interior region 521 includes an inner enclosure 580 and various components that interact with the inner enclosure 580. The inner enclosure 580 encloses a control board (CB) that includes a control system for a capacitor bank control system. A block diagram of an example of the control board is shown in FIG. 5. The control board may be implemented on a printed circuit board (PCB).

The inner enclosure 580 may be a metallic box or other housing to provide electromagnetic compatibility (EMC) compliance for the control board. A wire connector 586 is electrically connected to the control board and extends through the inner enclosure 580. The wire connector 586 is used to receive measured electrical data (for example, measured three-phase voltage and current values) and to provide command signals to a relay system that controls the electrical connections between a capacitor bank and an electrical power distribution system. The base 528 also includes a modem antenna 581. The interior region 521 also includes a model wire layout space 582, a door lock sensor 583, a GSM modem 584, a breaker 587, and earth lug 588, and connector pins 599. The breaker 587 is used as a power switch and eliminates the need for a separate fuse. Additionally, the interior region 521 includes a power source, such as a battery or super capacitor (such as the super capacitor 351 shown in FIG. 3). The power source may be mounted near the bottom of the base 528 (for example, near the earth lug 588). The power source is used to provide power to the control board during power outages in the electrical distribution system 190. This allows the control board to provide an outage notification during outages in the distribution system 190. Additionally, the control board may be connected to a display that mounts into or is aligned with an opening 543 on the inside of the door 525 with a keypad adjacent (for example, below) the display.

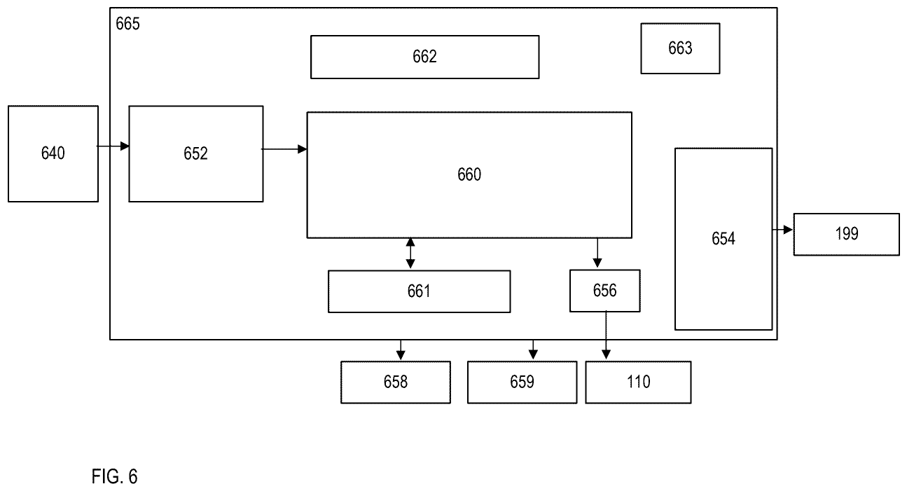

FIG. 6 is a block diagram of an example of a control board 665. The control board 665 may be enclosed in the inner enclosure 580 (FIG. 5). The control board 665 is used to control a three-phase capacitor bank, such as the capacitor bank 110. The control board 665 may be used in the capacitor bank control system 150. The control board 665 includes an electronic control 660 and an electronic storage 661 coupled to the electronic control 660. The electronic control 660 includes one or more electronic processors. The electronic processors may be any type of electronic processor and may or may not include a general purpose central processing unit (CPU), a graphics processing unit (GPU), a microcontroller, a field-programmable gate array (FPGA), Complex Programmable Logic Device (CPLD), and/or an application-specific integrated circuit (ASIC). The electronic storage 661 is any kind of electronic memory that is capable of storing executable instructions and data. In some implementations, the electronic storage 661 includes one or more of an embedded multimedia card (EmmC), Flash erasable programmable read-only memory (EPROM), and a double data rate (DDRx) memory.

The control board 665 also includes a relay system 656 that acts in response to a command signal from the electronic control 660. The relay system 656 includes 6 relays. The six relays include a trip relay and a close relay for each phase of the capacitor bank 110. To remove one of the phases of the capacitor bank 110, the electronic control 660 commands the trip relay to open the switching apparatus associated with that phase. To electrically connect one of the phases of the capacitor bank 110 to the distribution system 190, the electronic control 660 commands the close relay of that phase to close the switching apparatus associated with that phase. The electronic control 660 may control the relays in the relay system 656 individually (or per-phase) or simultaneously (ganged).

The control board 665 also includes a sensor system 652 that receives signals from sensors external to the control board 665. For example, the sensor system 652 may receive data and signals from voltage and/or current sensors that sense properties of the electricity that flows in the phase conductors 191a, 191b, 191c. The sensor system 652 may receive data and signals from a neutral current sensor that measures current in a neutral line of the distribution system. The sensor system 652 may filter the sensor data and/or convert the sensor data into a digital signal or other indication that is processed and analyzed by the electronic control. The sensor system 652 also may receive and process sensor data from sensors that monitor environmental conditions, such as humidity and temperature sensors.

The control board 665 also includes a power supply 662 that provides power for the various components of the control board 665, including the electronic control 660. The power supply 662 may be, for example, a battery. The power supply 662 is coupled to a power logic block 663. The power logic block 663 handles transfer of power between primary and backup power, backup power charging, and disabling or marking invalid any measurements from the power supply 662 when backup power is online.

The control board 665 also includes a communications device 654 that communicates with the remote station 199. The communications device 654 may include any type of communications device such as, for example, a radio, a modem, an Ethernet port, and/or a USB port. The communications device 654 may be used to provide an alert and/or a report to the remote station 199. The control board 665 provides output signals in other ways. For example, data received from the external sensors and/or generated by the electronic control 660 based on data received from the external sensor may be displayed on a display 659. The display 659 may be, for example, a liquid crystal display. Additionally, an operator may interact with the control board 665 through a keypad or other human-machine interface (HMI) 658.

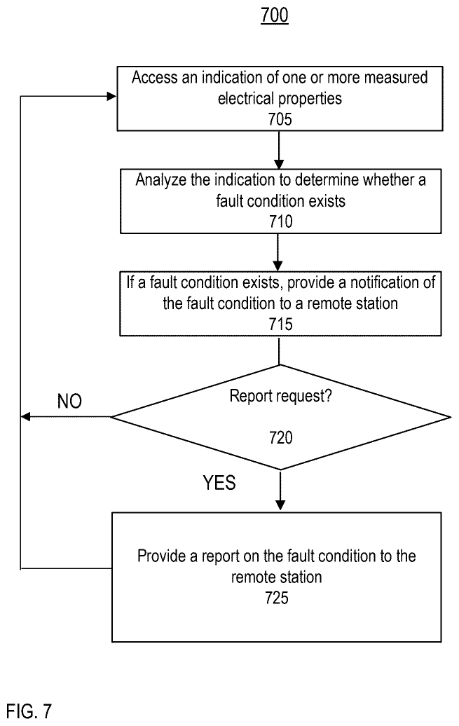

FIG. 7 is a flow chart of a process 700. The process 700 is an example of a process for detecting a fault condition in the power distribution system 190. The process 700 is implemented by the control board 665 (FIG. 6). The electronic storage 661 stores instructions that, when executed by the electronic control 660, perform the process 700. The electronic storage 661 also stores information used in the process 700.

An indication of one or more measured electrical properties is accessed (705). The indication of the measured property or properties is generated by the sensor system 652 based on data received from the external sensors 640. The data received from the external sensors 640 may include the value of the amplitude of the voltage and/or current in each phase conductor 191a, 191b, 191c sensed at many points over time.

The indications are analyzed to determine whether or not a fault condition exists in the distribution system 190 (710). Fault conditions may exist when there is an over-current or over-voltage in any of the phase conductors 191a, 191b, 191c. The over-current or over-voltage may be caused by a severed power line, faulty equipment, or water ingress into the phase conductors. Any approach may be used to analyze the indication to determine if a fault condition exists including but not limited to a rapid rise in current (determined by the change in current over time di/dt), a settable threshold or a settable percentage of nominal current above the expected value. A loss of current after a fault will classify it as a sustained fault, and a restoration of current will classify it as a momentary fault. In some implementations, the electronic control 660 analyzes the indication to determine whether there is a spike in the amplitude of the current in any of the phase conductors 191a, 191b, 191c followed by a loss of power over a pre-determined time period after the spike in current. The spike in current may be identified by comparing the indication of the amplitude of the measured current to a threshold value and declaring a spike if the threshold value is exceeded. The pre-determine time period may be set by the operator of the capacitor bank control system and stored in the electronic storage 661.

If a fault condition is identified, a notification is provided to the remote station 199 (715). The notification is sent through the communications device 654. The notification indicates that a fault is present and may provide additional information, such as the type of fault (for example, line-to-line or line-to-ground) and/or the location of the fault. The notification provides somewhat minimal information about the fault for the sake of efficiency. In some implementations, the communications device 654 can continue to send a notification at periodic intervals until an outage caused by the fault condition is resolved.

If a request for additional information (720) is received through the communications device 654 or the keypad 658, a full report on the fault condition is presented at the display 659 and/or sent to the remote station 199 via the communications device 654. The full report may include, for example, oscillography of the current and/or voltage waveforms that were used to identify the fault. The data in the report may be represented by a large data file. Thus, sending the report only in response to a request instead of by default promotes efficiency.

The process 700 may include additional features. For example, an operator may identify current and/or voltage waveforms in the report and save the waveform in a library on the electronic storage 661. The waveforms in the library may be compared against future waveforms received at the sensor system 652 to improve the speed and accuracy of fault detection. Furthermore, the operator may tag or associate each waveform with a particular fault-causing condition. Examples of fault-causing conditions include, without limitation, downed conductors and malfunctioning equipment.

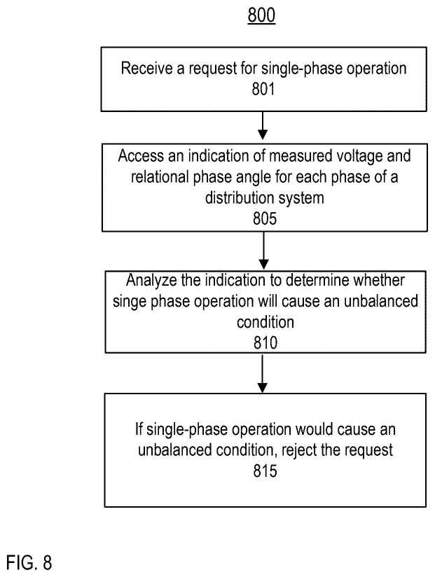

FIG. 8 is a flow chart of a process 800. The process 800 is an example of a process for preventing an unbalance condition in the power distribution system 190 that could be caused by a single-phase operation requested by the capacitor bank control system 150. Single-phase operation of the capacitor bank 110 occurs when one phase of the capacitor bank 110 is connected to or disconnected from its respective phase conductor. The process 800 is implemented by the control board 665 (FIG. 6). The electronic storage 661 stores instructions that, when executed by the electronic control 660, perform the process 800. The electronic storage 661 also stores information used in the process 800.

A request for single-phase operation of the capacitor bank 110 is received (801). A measurement of the voltage and relational phase angle on each phase is taken (805). The measurements are based on voltages measured directly at each phase conductor 191a, 191b, 191c or on an estimate of the voltage at each phase conductor 191a, 191b, 191c derived from another measurement (such as a current measurement). The indication is analyzed to determine whether single-phase operation of the capacitor bank 110 would cause an unbalanced condition (810). Nominally, the amplitude of the voltage on each phase conductor 191a, 191b, 191c is the same and 120° out of phase with the other two phases. The voltage in the distribution system 190 is considered unbalanced when the amplitude and/or phase of the voltage on one of the three phases is different than the nominal amplitude and/or phase condition by more than a threshold amount. If single-phase operation of the capacitor bank 110 would cause an unbalanced condition, the request for single-phase operation is rejected (815).

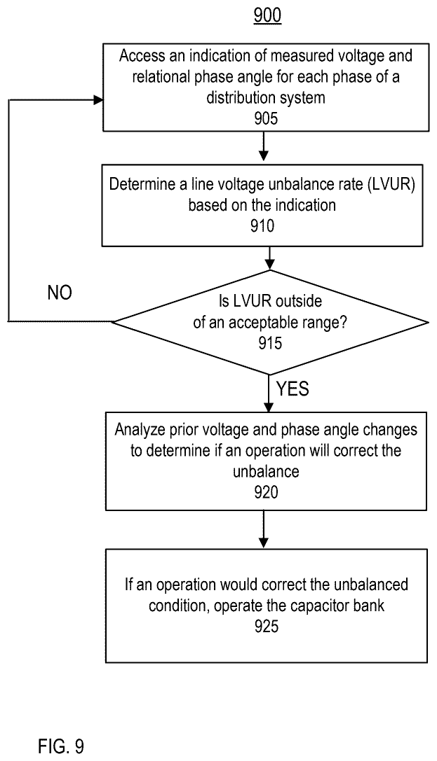

FIG. 9 is a flow chart for a process 900. The process 900 is an example of a process for evaluating and detecting an unbalance system and correcting it by requesting a single-phase operation of the capacitor bank 110. A measurement of the voltage and relational phase angle on each phase is taken (905). The measurements are based on voltages measured directly at each phase conductor 191a, 191b, 191c or on an estimate of the voltage at each phase conductor 191a, 191b, 191c derived from another measurement (such as a current measurement). The indication is are used to determine a line voltage unbalance rate (LVUR) at (910). An example of analysis for determining the LVUR is shown in Equations (1) to (4):

$$\frac{{V}_{a} + {V}_{b} + {V}_{c}}{3} = {V}_{AVG} , \qquad Equation ( l )$$

where Va is the voltage in the phase conductor 191a, Vb is the voltage in the phase conductor 191b, Vc is the voltage in the phase conductor 191c, and Vavg is the average voltage. The deviation of each phase from the average (Vavg) is determined by:

$$\vert {V}_{a} - {V}_{AVG} \vert = {V}_{DEVa} , \qquad Equation ( 2 a )$$

$$\vert {V}_{b} - {V}_{AVG} \vert = {V}_{DEVb} , \qquad Equation ( 2 b )$$

$$\vert {V}_{c} - {V}_{AVG} \vert = {V}_{DEVc} , \qquad Equation ( 2 c )$$

where Vdeva is the deviation in the phase conductor 191a, Vdevb is the deviation in the phase conductor 191b, and Vdevc is the deviation in the phase conductor 191c. The phase with the maximum deviation from the average (Vavg) is determined by:

$$MAX ( {V}_{DEVa} , {V}_{DEVb} , {V}_{DEVc} ) = {V}_{DEVmax} , \qquad Equation ( 3 )$$

where Vdevmax is the maximum deviation. The line voltage unbalance rate is determined by:

$$\frac{{V}_{DEVmax}}{{V}_{AVG}} \times 100 = LVUR , \qquad Equation ( 4 )$$

where LVUR is the line voltage unbalance rate.

The LVUR is compared to a range of acceptable LVUR values. The range of acceptable LVUR values may be stored on the electronic storage 661 and may be set by an operator of the capacitor bank control system 150. If the LVUR is outside the range of acceptable LVUR values (915), the process 900 analyzes voltage and phase angle changes that occurred due to one or more previous operations of the capacitor bank 110 to determine whether operating the capacitor bank 110 will correct the voltage imbalance and bring the LVUR into the range of acceptable LVUR values. Information related to the voltage and phase angle changes that occurred due to one or more previous operations of the capacitor bank 110 are stored on the electronic storage 661. For example, if the previous operations of the capacitor bank 110 resulted in voltage and/or phase angle changes sufficient to bring the LVUR into the range of acceptable values, then operating the capacitor bank 110 would also correct the existing unbalance. If operating the capacitor bank 110 would correct the voltage imbalance, the electronic control 660 commands the relay system 656 to connect or disconnect one of the phases of the capacitor bank 110 from its corresponding phase conductor (925).

The process 900 may include additional features. For example, a mechanism or counter may be tracked to monitor the number of operations of the capacitor bank 110 over time (for example, the number of operations in a day). In some implementations, the electronic control 660 does not command the relay system 656 to operate the capacitor bank 110 if more than a pre-determined number of operations have occurred within a defined time period.

Moreover, the capacitor bank control system 150 may be configured to perform additional operations. For example, in some implementations, the capacitor bank control system 150 includes a capacitor bank commissioning wizard. The commissioning wizard may be performed by the control board 665 and implemented as a set of executable instructions stored on the electronic storage 661 and performed by the electronic controller 660. The commissioning wizard is a process to automate capacitor bank commissioning using real time information and a lookup table. The lookup table is stored on the electronic storage 661. The following information is stored on the electronic storage 661 or otherwise available to the electronic control 660: the size of the capacitor bank (this value can be divided by 3 to calculate the capacitors installed on an individual phase), the state of the switch apparatuses 114a, 114b, 114c using, for example, 52A/B contacts, the measured Voltage Change caused by an operation of the capacitor bank 110, the measured Current change caused by an operation of the capacitor bank 110, the measured reactive power (VAR) change caused by an operation of the capacitor bank 110, the measured kW change caused by an operation of the capacitor bank 110, the measured kVA change caused by an operation of the capacitor bank 110, the measured phase angle change caused by an operation of the capacitor bank 110, the measured Power Factor change caused by an operation of the capacitor bank 110, what relay of the relay system is being operated to exercise the switches 114a, 114b, 114c.

Via the HMI 658, a user is guided through basic settings and these settings can checked and adjusted with subsequent bank operations. For example, a wiring verification may be performed. The capacitor bank control system 150 inputs and outputs are user-programmable to match the phases the inputs and outputs are installed on. This can be done on banks that are wired for ganged or single-phase operation. Once a user has programmed the device, a wiring verification method can be run. The user is notified that the capacitor bank 110 will operate. The capacitor bank 110 will then attempt to operate the first phase (for example, 112a) using the programmed relays. It will then verify that the correct switch operated by using any method including but not limited to the following: Voltage change on the specified phase, VAR change on the specified phase, the state of the switch using the 52A/B contacts. If an incorrect switch operated, the user can be notified via the front panel HMI 658 that the wiring should be changed, or the capacitor bank control 150 can make the change and restart the verification process. This process is then repeated for the additional phases.

The capacitor bank controls system 150 also may perform a phase angle verification. In order to account for inputs on different phases or current sensors that induce a phase shift in relation to voltage, a phase angle correction may be made. Once the user has programmed the device, a phase angle verification method can be run. The user is notified that the bank will operate. The bank will then attempt to operate all phases of the bank. By documenting kW, kvar, kVA, Phase Angle, and Power Factor before and after the operation, the control can determine the correct phase angle adjust by using any method including but not limited to: brute force calculating the phase angle adjust that brings the kw change closest to OkW, brute force calculating the phase angle adjust that brings the kvar change closest to the configured bank size. Once the ideal phase angle adjust is found, the user can be notified via the front panel HMI 658 what the phase angle adjust needs to be changed to, or the capacitor bank control can make the required change and restart the phase angle verification process.

These and other implementations are within the scope of the claims.

What is claimed is:

1. A control system comprising:
a sensor system configured to produce an indication of one or more measured electrical properties of a multi-phase electrical distribution system;
a relay system configured control an electrical connection between the electrical distribution system and a capacitor bank;
a communications device; and
a controller coupled to the communications device, the controller configured to:
access the indication of the one or more measured electrical properties of the multi-phase electrical distribution system;
analyze the indication of the one or more measured electrical properties of the multi-phase electrical distribution system to determine whether a fault condition exists in the multi-phase electrical distribution system; and
if a fault condition exists, provide a notification of the fault condition to a remote device through the communications device.

2. The control system of claim 1, wherein the controller is configured determine whether the indication of the one or more measured electrical properties comprises a spike in amplitude of electrical current followed by a loss of power over a predetermined time period in one or more phases of the electrical distribution system to determine whether the fault condition exists.

3. The control system of claim 1, wherein the predetermined time period is a user-entered value.

4. The control system of claim 3, wherein the controller is further configured to provide a report regarding the fault condition to the remote device in response to a request for the report.

5. The control system of claim 4, wherein the report comprises one or more of a type of fault condition, a direction of the fault condition, a location of the fault condition, and oscillography related to the fault condition.

6. The control system of claim 5, wherein the controller comprises an electronic storage, the electronic storage comprising a library of waveforms, each waveform associated with one or more known types of fault conditions.

7. The control system of claim 5, wherein the controller is further configured to compare a representation of a waveform based on the indication of the one or more measured electrical properties of the multi-phase electrical distribution system to waveforms in the library of waveforms to identify the type of fault condition.

8. A control system comprising:
a sensor system configured to produce an indication of one or more measured electrical properties of each phase of a multi-phase electrical distribution system;
a relay system configured control a plurality of electrical connections, each electrical connection being between one phase of the electrical distribution system and a corresponding phase of a capacitor bank; and
a controller configured to:
access the indication of the one or more measured electrical properties of the multi-phase electrical distribution system;
analyze the indication of the one or more measured electrical properties of the multi-phase electrical distribution system to determine whether an unbalanced condition exists in one or more of the phases of the electrical distribution system; and
if an unbalanced condition exists, cause the relay system to control at least one electrical connection between at least one phase of the electrical distribution.

9. The control system of claim 8, wherein the controller is configured to analyze the indication of the one more measured electrical properties to determine if an imbalance exists in the multi-phase electrical distribution system, and, if an imbalance exists, cause the relay system to control the electrical connection between any of the phases of the capacitor bank individually or all of the phases of the capacitor bank simultaneously based on the analysis.

10. The control system of claim 8, wherein, before causing the relay system to control the at least one electrical connection, the controller is further configured to determine whether controlling the at least one electrical connection would correct the unbalanced condition.

11. An enclosure for a controller, the enclosure comprising:
a housing comprising: a base portion with an interior region, and a cover configured to be attached to and removed from the base portion, wherein, when the cover is attached to the base portion, the interior region is enclosed;
a metallic housing in the interior region;
a connector that extends through the metallic housing and is coupled to the control system, the connector configured to receive an indication of one or more measured electrical properties in an electrical distribution system and to provide a control signal to a relay;
a control system in the metallic housing and coupled to the connector, the control system configured to generate the control signal based on the indication of the one or more measured electrical properties;
a communications device configured to communicate with the control system; and
a power source in the interior region and electrically connected to the control system and the communications device.

12. The enclosure of claim 11, wherein the cover comprises a door attached to one side of the base.

13. The enclosure of claim 11, wherein the communications device comprises a modem, and the enclosure further comprises a breaker configured as a power switch in the interior region.

14. An enclosure for a capacitor bank controller, the enclosure comprising:
a base comprising: a plurality of sidewalls and a back portion, a first side of each of the plurality of sidewalls and the back portion defining an interior region, wherein a second side of a first one of the sidewalls comprises a latch connection region;
a cover rotatably mounted to a second one of the sidewalls and configured to rotate about the second one of the sidewalls; and
a latch mounted to a first side of the cover, wherein, when the cover is positioned with the cover over the interior region, the latch is aligned with the latch recess, a second side of the cover faces the interior region, and the latch comprises a single-piece handle configured to be secured to the latch connection region with a single movement.

15. The enclosure of claim 14, wherein the second side of the first one of the sidewalls further comprises a handle.

16. The enclosure of claim 15, wherein the handle comprises a recess in the second side of the first one of the sidewalls.

17. The enclosure of claim 14, wherein the second one of the sidewalls is parallel to the first one of the sidewalls.

18. The enclosure of claim 14, wherein each of the second side of the first one of the sidewalls and the second side of the second one of the sidewalls comprises a respective first and second handle.

19. The enclosure of claim 18, wherein the first handle comprises a recess in the second side of the first one of the sidewalls, and the second handle comprises a recess in the second side of the second one of the sidewalls.

20. The enclosure of claim 14, further comprising a hanging bracket configured to attach to a second side of the back portion, wherein the hanging bracket comprises an interface configured to attach the enclosure to a utility structure.

21. A control system comprising:
a sensor system configured to produce an indication of one or more measured electrical properties of each phase of a multi-phase electrical distribution system;
a relay system configured control a plurality of electrical connections, each electrical connection being between one phase of the electrical distribution system and a corresponding phase of a capacitor bank; and
a controller configured to perform an automated commissioning of the capacitor bank, the automated commissioning comprising the controller being configured to:
present information related to settings;
perform wiring verification to confirm that the capacitor bank operates;
if the capacitor bank operates, cause the relay system to control a switch on the electrical connection between one phase of the distribution system and the corresponding phase of the capacitor bank; and
confirm that the switch operated.
